(19) United States
(12) Patent Application Publication
(10) Pub. No.: US 2019/0263023 A1
(43) Pub. Date: Aug. 29, 2019

(54) SYSTEM AND METHOD FOR CONSTRUCTING A ROLLER-TYPE NANOIMPRINT LITHOGRAPHY (RNIL) MASTER

(71) Applicant: Carpe Diem Technologies, Inc., Franklin, MA (US)

(72) Inventors: John S. Berg, Mattapoisett, MA (US); Dimitur Benchev, Norwood, MA (US); Sondre Brandso, Somerset, MA (US)

(21) Appl. No.: 16/286,127

(22) Filed: Feb. 26, 2019

Related U.S. Application Data
(60) Provisional application No. 62/778,447, filed on Dec. 12, 2018.
(60) Provisional application No. 62/635,223, filed on Feb. 26, 2018.

(51) Int. Cl. B29C 33/38; G03F 7/039; G03F 7/20; G03F 7/38; G03F 7/32; G03F 7/16; G03F 7/40

(52) U.S. Cl. CPC B29C 33/3842; G03F 7/039; G03F 7/2006; G03F 7/38; G03F 7/0002; G03F 7/16; G03F 7/168; G03F 7/40; G03F 7/32

(57) ABSTRACT

A system for constructing a roller-type nanoimprint lithography (RNIL) master comprises a master fabrication tool positioned in relation to a metal sleeve which is axially mounted on a rotatable drum. As part of the manufacturing process, the metal sleeve is applied with a layer of photoresist. Then, a laser writing instrument for the master fabrication tool exposes the photoresist in a defined, controller-regulated pattern using highly-focused pulses of light. Using alignment fiducials on the metal sleeve for registration, the laser writing instrument sensitizes the photoresist in a designated pattern as the rotatable drum continuously moves both rotationally and linearly about its longitudinal axis. In connection with one manufacturing process, the photoresist is sensitized at variable depths by modifying the number, duration and intensity of light pulses emitted. Thereafter, light-sensitized photoresist is removed during a development step, with the remaining photoresist hardened and coated to yield a high-precision feature pattern.

### CROSS-REFERENCE TO RELATED APPLICATIONS

The present application claims the benefit under 35 U.S.C. 119(e) of U.S. Provisional Patent Application No. 62/778,447, inventors John S. Berg et al., filed Dec. 12, 2018 and U.S. Provisional Patent Application No. 62/635,223, inventors John S. Berg et al., filed Feb. 26, 2018, both disclosures being incorporated herein by reference.

### FIELD OF THE INVENTION

The present invention relates generally to the fabrication of miniature structures and, more particularly, to the construction of miniature structures using nanoimprint lithography.

### BACKGROUND OF THE INVENTION

Nanoimprint lithography, or NIL, is a nanofabrication technology that relies upon the direct physical deformation of a designated surface on a particular material to create nanometer-scale structures. Specifically, a stamp, also commonly referred to in the art as an imprint mold or template, has a relief surface with patterns that are often micrometer or nanometer in scale, the patterns being formed using high precision formation techniques, such as electron beam lithography, focused ion beam milling, dry etching and the like.

To manufacture nanostructures through nanoimprint lithography, the patterned surface of the imprint mold is drawn into direct contact with imprint resist which is coated on a substrate, typically through a spin coating process. As a result of physical contact with the imprint mold, the resist deforms in the particular pattern defined by the complementary imprint mold. Through a designated curing process (e.g. through the application of heat or light), the resist is hardened in the specific deformation pattern. Subsequently, a pattern transfer process, such as reactive ion etching, is undertaken to transfer the pattern in the resist onto the substrate.

As a result, nanoimprint lithography enables nanoscale structures to be fabricated on a variety of different substrate materials through a pattern transfer process that operates in an inexpensive and highly precise fashion, which is highly desirable.

Often, the imprint mold, or stamp, serves as a critical factor in the overall success in fabricating miniature structures using nanoimprint lithography.

For instance, the ultimate resolution of patterns fabricated through nanoimprint lithography is largely is dependent upon the precision of the features that can be formed on the NIL stamp. Although current techniques allow for template patterning with relatively high precision, these techniques are generally laborious, time consuming and expensive to implement. As a result, there is currently no high yield, low cost solution for fabricating NIL stamps.

Additionally, the durability and reliability of a NIL stamp can directly affect fabrication costs, with many stamps having a limited lifespan in the order of 500 stamping cycles. Accordingly, it has been found that in order to generate millions of products using nanoimprint lithography, thousands of complementary NIL stamps are typically required.

Lastly, NIL imprint molds are commonly constructed as limited-sized discs or plates. To improve throughput, multiple individual patterned discs are often laser welded together to form a larger imprint mold. However, the connection of multiple individual discs can create seams which, in turn, can compromise output quality.

In response to many of limitations set forth above in conjunction with traditional NIL stamps, roller-type nanoimprint lithography, or RNIL, has recently been developed to allow for continuous patterning and, as a result, greater throughput. In roller-type nanoimprint lithography, an externally patterned, cylindrical roller, or master, is drawn into direct physical contact with a web as part of a continuous, roll-to-roll, pattern transfer process with nanoscale capabilities.

However, as with most NIL stamps, it has been found that roller-type masters are similarly difficult to construct with precise features in an inexpensive manner. Additionally, as with most NIL stamps, roller-type masters have a limited lifespan and therefore require frequent replacement in high-throughput applications.

### SUMMARY OF THE INVENTION

It is an object of the present invention to provide a new and improved system and method for constructing a roller-type nanoimprint lithography (RNIL) master.

It is another object of the present invention to provide a system and method as described above that is capable of producing an RNIL master having a relief surface with a highly precise feature pattern.

It is yet another object of the present invention to provide a system and method as described above that is capable of producing an RNIL master with a relief surface in the absence of seams.

It is still another object of the present invention to provide a system and method as described above that is capable of producing a durable RNIL master in a simple and inexpensive manner.

Accordingly, as a feature of the invention, there is provided a method of manufacturing a roller-type nanoimprint lithography (RNIL) master, the method comprising the steps of (a) mounting an RNIL master on a rotatable axle, the rotatable axle having a longitudinal axis, (b) applying a layer of photoresist on the RNIL master, (c) positioning a writing instrument in relation to the RNIL master, the writing instrument being adapted to emit pulses of light of a first wavelength, and (d) exposing the photoresist in a defined pattern on the RNIL master using pulses of light emitted from the writing instrument.

Various other features and advantages will appear from the description to follow. In the description, reference is made to the accompanying drawings which form a part thereof, and in which is shown by way of illustration, an embodiment for practicing the invention. The embodiment will be described in sufficient detail to enable those skilled in the art to practice the invention, and it is to be understood that other embodiments may be utilized and that structural changes may be made without departing from the scope of the invention. The following detailed description is therefore, not to be taken in a limiting sense, and the scope of the present invention is best defined by the appended claims.

### BRIEF DESCRIPTION OF THE DRAWINGS

In the drawings, wherein like reference numerals represent like parts:

FIG. 1 is a fragmentary, front perspective view a system for constructing a roller-type nanoimprint lithography (RNIL) master, the system being constructed according to the teachings of the present invention;

FIG. 2 is a fragmentary, left end perspective view of the system shown in FIG. 1;

FIG. 3 is a partially exploded, left end perspective view of selected components of the system shown in FIG. 1 which are useful in illustrating the construction of the RNIL master;

FIG. 4 is an exploded, top perspective view of the laser writing instrument shown in FIG. 1;

FIG. 5 is a front perspective view of the master construction system of FIG. 1, the master construction system being shown housed within a clean enclosure;

FIGS. 6(a)-(i) are a series of section views depicting the manufacture of an RNIL master using a novel master construction method which relies upon the master construction system of FIG. 1, the master construction method is described in detail herein in accordance with the teachings of the present invention;

FIG. 7 is a simplified optical schematic of the laser writing instrument shown in FIG. 1, the laser writing instrument being shown in relation to the RNIL master in order to illustrate how the laser writing instrument can be used to create alignment fiducials in the RNIL master;

FIG. 8 is a simplified optical schematic of the laser writing instrument shown in FIG. 1, the laser writing instrument being shown in relation to the RNIL master in order to illustrate how the laser writing instrument can be used to expose photoresist on the RNIL master as a matrix of highly focused, light pulse spots that together form a defined pattern;

FIG. 9(a) is an enlarged, simplified, optical schematic of the laser writing instrument shown in FIG. 8 at the surface of the RNIL master on which light is illuminated;

FIG. 9(b) is an enlarged, simplified, optical schematic of the laser writing instrument shown in FIG. 9(a) which has been modified to include an immersion lens in near tangential contact with RNIL master; and

FIGS. 10(a)-(j) are a series of section views depicting the manufacture of an RNIL master using a modification to the master construction method represented in FIGS. 6(a)-(i).

### DETAILED DESCRIPTION OF THE INVENTION

### Master Construction System 11

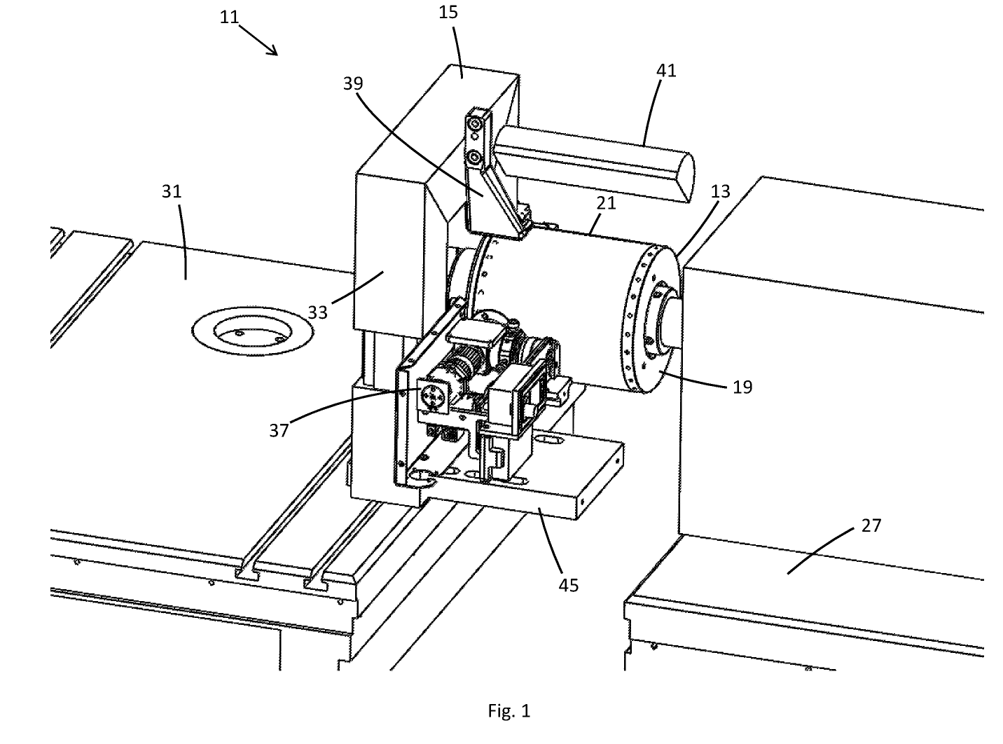

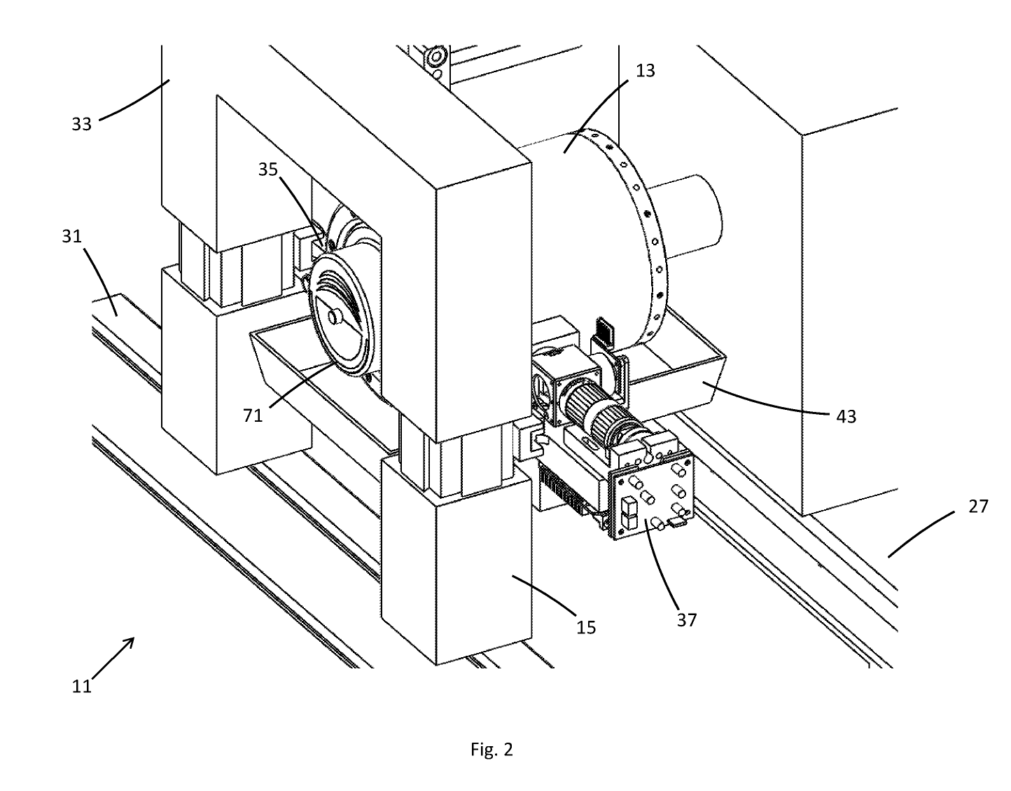

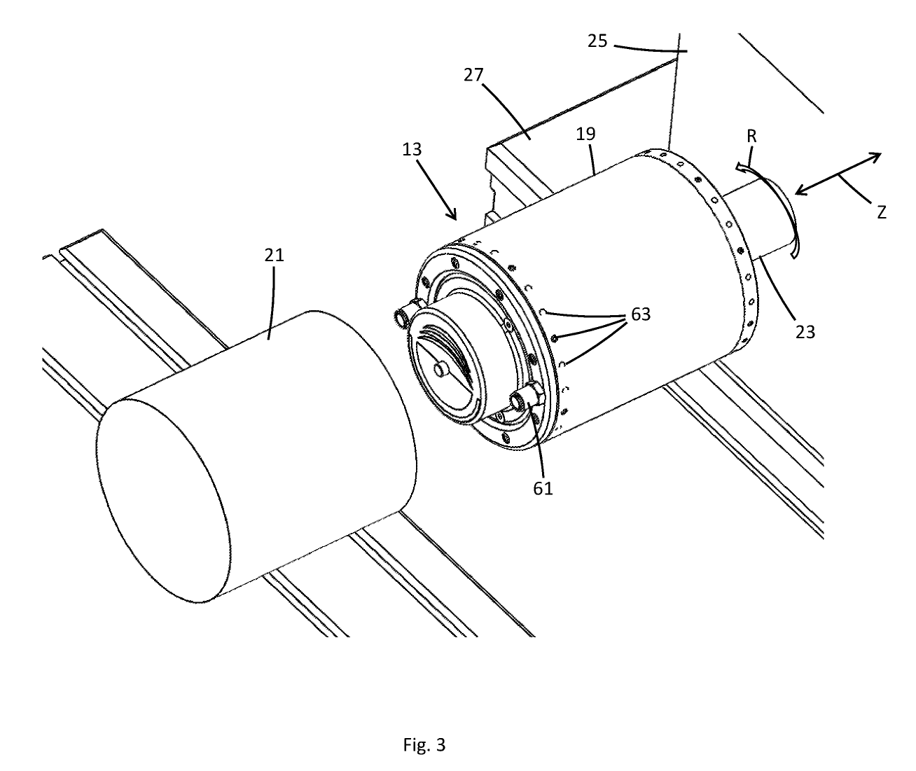

Referring now to FIGS. 1 and 2, there are shown front perspective and left end perspective views, respectively, of a system for constructing a roller-type nanoimprint lithography (RNIL) master, the system being constructed according to the teachings of the present invention and identified generally by reference numeral 11. As will be explained in detail below, master construction system 11 selectively exposes photoresist coated on a rotatable cylindrical sleeve in order to create nanoscale patterns onto a roller-type master mold, or master.

As shown herein, system 11 comprises an RNIL master 13 and a master fabrication tool 15. As will be described in detail below, master fabrication tool 15 includes a unique collection of instruments that allow for nanoscale patterns to be formed onto master 13 as part of a novel RNIL master construction process.

For purposes of simplicity and ease of illustration, all of the various instruments that are used to perform the novel master fabrication process are shown as being integrated into a unitary, single-station, master fabrication tool 15. However, it is to be understood that one or more of these instruments could be disassociated therefrom and positioned at separate master fabrication stations without departing from the spirit of the present invention.

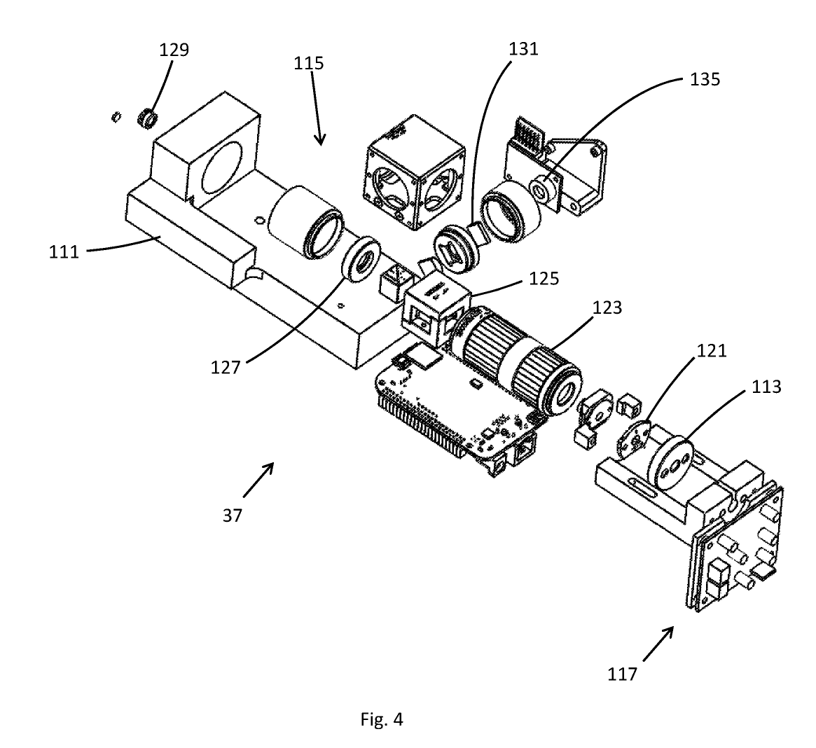

As seen most clearly in FIG. 3, RNIL master 13 comprises a cylindrical drum 19 onto which is fittingly mounted a nickel sleeve 21. In turn, drum 19 is fixedly mounted onto a spindle, or axle, 23 which is coupled to a box-shaped housing 25. To assist in the alignment of master 13 relative to tool 15, housing 25 is preferably fixedly mounted onto a stable support structure 27, such as a table.

A motor (not shown) precisely controls movement of spindle 23 (and, as such, drum 19 and sleeve 21 mounted thereon) along both (i) a rotational path about the longitudinal axis of spindle 23, as represented by arrow R, and (ii) a linear path in parallel with the longitudinal axis of spindle 23 (i.e. along its Z-axis), as represented by arrow Z. In this manner, a controller (not shown) can be used to position any location on nickel sleeve 21 relative to the various instruments of tool 15, as will be explained further in detail below.

Referring back to FIGS. 1 and 2, master fabrication tool 15 is constructed as a unitary device that is fixedly mounted onto a support structure 31 in close proximity to support structure 27. Alternatively, it is to be understood that RNIL master 13 and master fabrication tool 15 could be fixedly mounted onto a common support structure in order to create a smaller overall footprint for system 11.

Master fabrication tool 15 comprises an inverted U-shaped frame, or base, 33 that is fixedly mounted onto support structure 31. Additionally, as referenced above, tool 15 includes a plurality of individual instruments that are mounted onto frame 33 and are utilized at various stages of the novel master fabrication process to be described in detail below.

More specifically, tool 15 comprises, inter alia, a diamond cutting instrument 35, a laser writing instrument 37, an inkjet head 39, an infrared (IR) heater 41, and a collection tray, or pan, 43 that is removably mounted onto a base plate 45 which is coupled to frame 33. One or more controllers (not shown) regulate operation of the various instruments of tool 15 and provide means for user interaction.

As will be explained further in detail below, laser writing instrument 37 is preferably designed to pulse highly focused spots of ultraviolet (UV) light onto RNIL master 13. In this manner, UV light generated from laser writing instrument 37 can be used to assist in both the acute alignment and patterning of RNIL master 13.

As seen most clearly in FIG. 4, laser writing instrument 37 comprises a two-piece base, or housing, 111 that is designed to support the various components of instrument 37, a light source 113 mounted on base 111, an optical system 115 for focusing light produced from light source 113 onto RNIL master 13, and electronics 117 for controlling operation of light source 113.

More specifically, optical system 115 comprises a collimating lens 121 and beam expander 123 that direct light produced from light source 113 onto a polarizing beam splitter 125. In turn, polarizing beam splitter 125 transmits p-polarized light, while reflecting s-polarized light. The p-polarized light is directed through a quarter-wave plate 127 and one or more focusing lenses 129 to yield a focused, spot-sized, pulse of light onto the desired surface, as will be explained further in detail below. The s-polarized light is directed through at least one lens 131 and onto a quad-focus detector 135. As will be explained further below, detector 135 assists in the acute alignment, or registration, of instrument 37 relative to RNIL master 13, thereby affording system 11 with great precision in writing patterns onto master 13.

Light source 113 is represented herein as a UV laser diode that emits light capable of modulation within a designated UV frequency range. Preferably, light produced from light source 113 falls within a specific range of relatively short wavelengths, as shorter wavelength light is preferred in order to write with the high level of precision and resolution required to create nanoscale features. For instance, in the present application, light source 113 is preferably designed to emit 405 nm light. However, it is to be understood that shorter wavelength light (e.g., 365 nm, 255 nm, or 190 nm light) could be used in place thereof to achieve even greater resolution and accuracy.

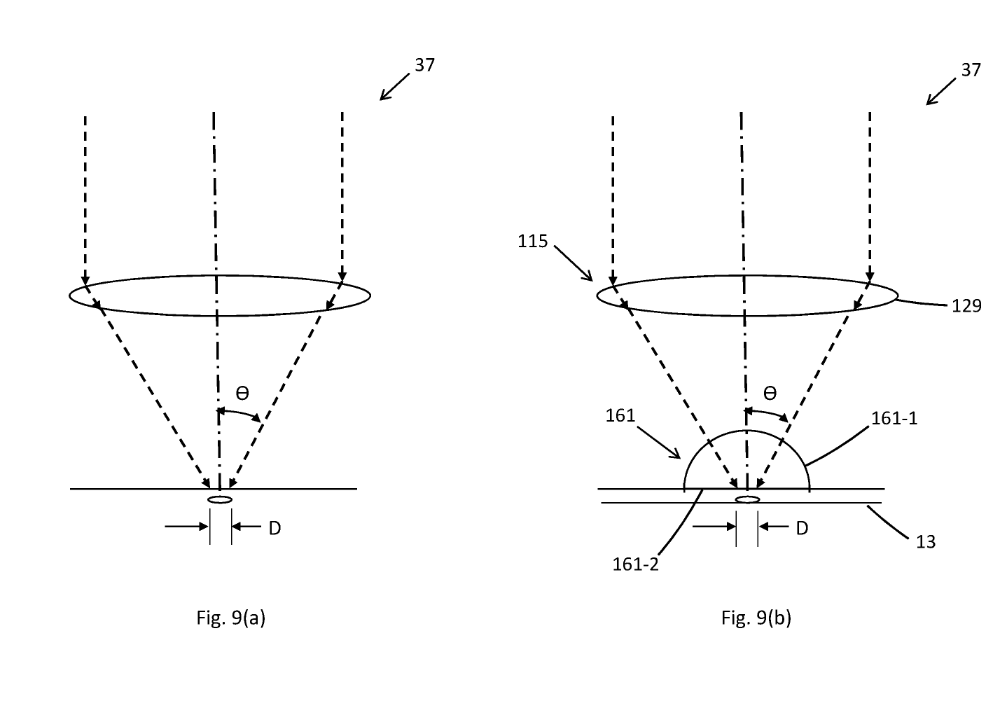

As referenced briefly above, laser writing instrument 37 is designed to pulse highly focused spots of UV light. As seen most clearly in FIG. 9(a), laser writing instrument 37 produces light with a spot diameter, D, that can be approximated using the following equation, wherein A represents the wavelength of light pulsed from light source 113 and NA represents the numerical aperture associated with optical system 115:

D=(0.6*λ)/NA

Accordingly, with a laser writing instrument 37 that emits 405 nm light and has a numerical aperture of approximately 0.65, spots of UV light can be generated that have a width, or diameter, of approximately 400 nm. By shortening the wavelength of light emitted from light source 111 (e.g. to 190 nm) and increasing the numerical aperture of optical system 115 (e.g. to as much as 2.0 through the integration of immersion optics, as shown in FIG. 9(b)), it is envisioned that UV light spots pulsed from instrument 37 could be reduced to less than 50 nm in diameter.

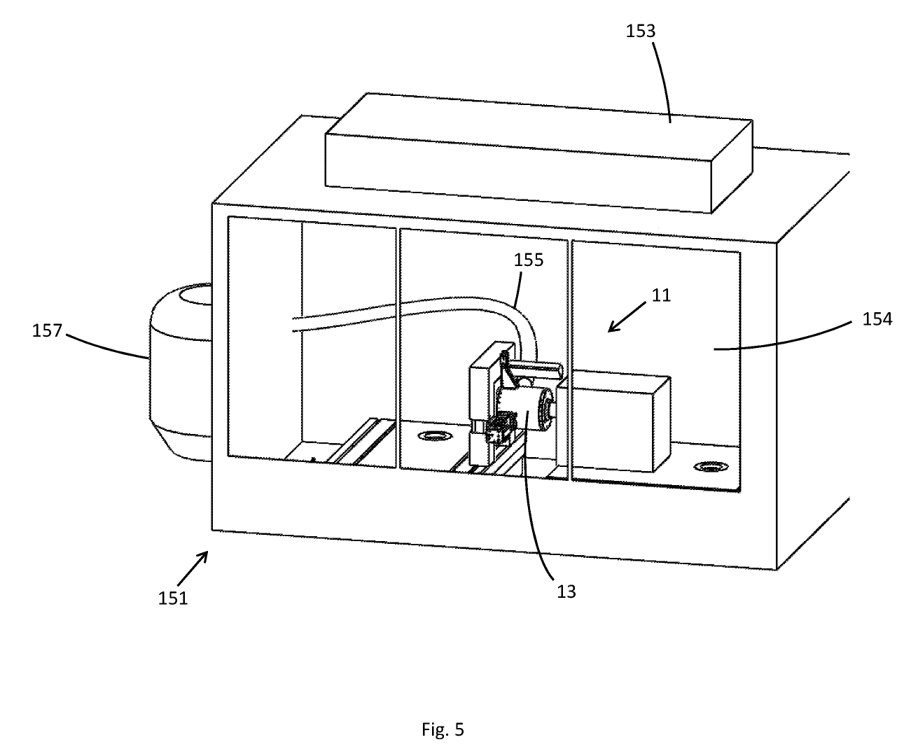

To minimize the presence of any particulates created during the fabrication of RNIL master 13 (e.g. as a result of diamond turning processes), it is envisioned that system 11 may be enclosed within an environment that is specifically designed to remove such contaminants. For instance, in FIG. 5, system 11 is shown contained within a clean enclosure 151. As can be seen, a high efficiency particulate air (HEPA) filter 153 is integrated into enclosure 151 to introduce a laminar flow of clean air into the pressurized interior cavity 154 of enclosure 151. Additionally, the free end of a suction hose 155 is positioned within interior cavity 154 in close proximity to RNIL master 13, the suction hose 155 being connected to an external vacuum cleaner 157. In this manner, cleaner 157 is designed to extract contaminants from enclosure 151 via hose 155. Although not shown herein, a voltage source may be applied to the RNIL master 13 during the diamond turning process to eject shaved portions of the sleeve away therefrom to assist in the particle vacuuming process.

### Master Construction Method

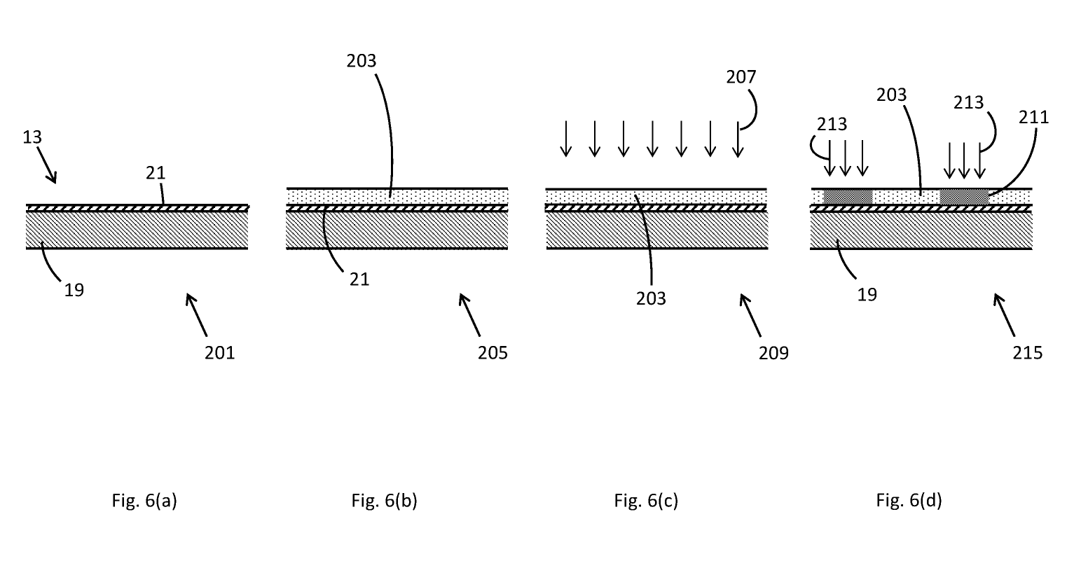

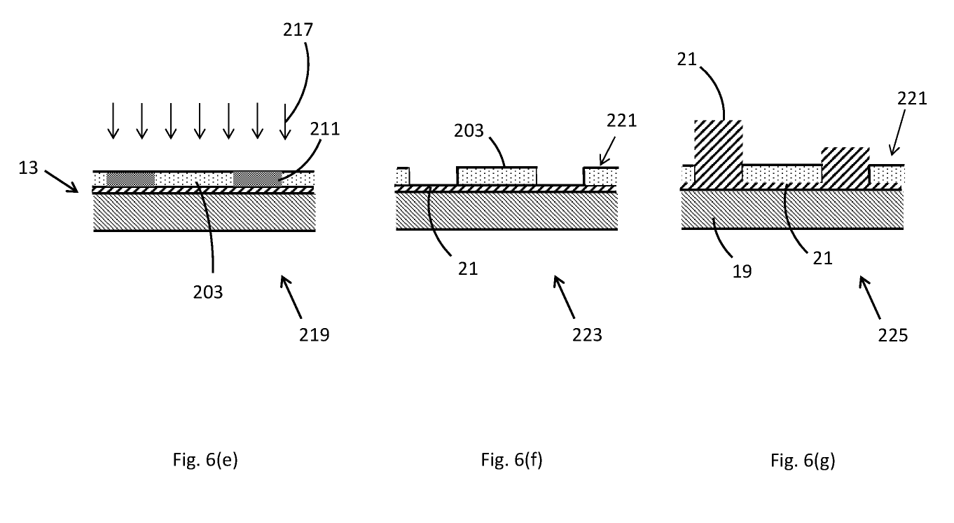

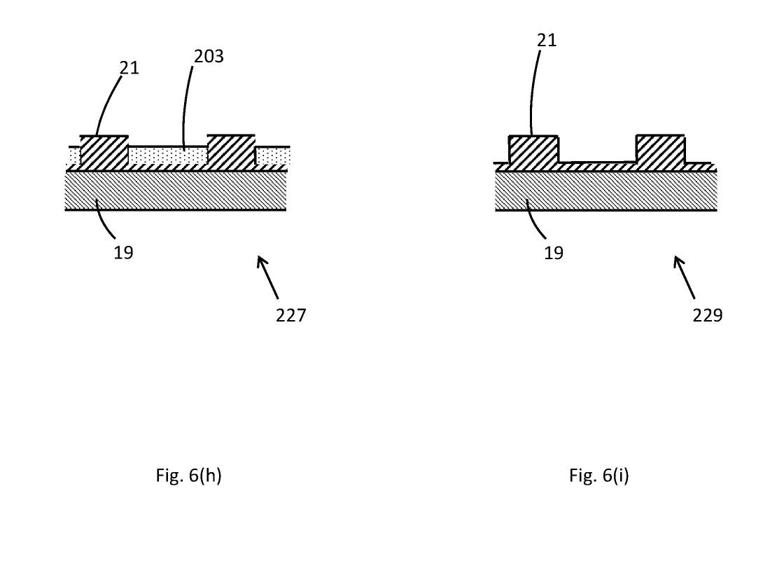

Referring now to FIGS. 6(a)-(i), master 11 is preferably formed using a novel master construction method, the method being described in detail herein. As will be explained in detail below, the master fabrication method incorporates a series of novel steps which together allow for the creation of a RNIL master 13 with very accurate and precise features, which is a principal object of the present invention.

As set forth in detail below, the master fabrication method comprises the principal steps of (i) setting up RNIL master 13 for subsequent patterning, the aforementioned set-up step being identified generally by reference numeral 201 in FIG. 6(a), (ii) coating RNIL master 13 with photoresist 203, the photoresist coating step being identified generally by reference numeral 205 in FIG. 6(b), (iii) pre-baking photoresist 203 with infrared heat 207 to remove solvent therefrom, the pre-baking step being identified generally by reference numeral 209 in FIG. 6(c), (iv) writing alignment fiducials and an image pattern 211 into photoresist 203 on RNIL master 13 using UV light 213 pulsed as a matrix of highly focused spots, the laser image writing, or patterning, step being identified generally by reference numeral 215 in FIG. 6(d), (v) post-baking photoresist 203 on RNIL master 13 using IR heat 217, the post-baking step being identified generally by reference numeral 219 in FIG. 6(e), (vi) chemically developing a patterned mask 221 by removing the UV-exposed, positive-type, photoresist 203 from master 13, the developing step being identified generally by reference numeral 223 in FIG. 6(f), (vii) electroplating nickel sleeve 21 through the patterned mask 221 defined by the remaining photoresist 203, the electroplating step being identified generally by reference numeral 225 in FIG. 6(g), (viii) cutting electroplated nickel sleeve 21 to the target feature height, the cutting step being identified generally by reference numeral 227 in FIG. 6(h), and (ix) stripping any remaining photoresist 203 to yield the finished pattern, or mold, for RNIL master 13, the photoresist stripping step being identified generally by reference numeral 229 in FIG. 6(i).

Further details with respect to each step of the aforementioned master fabrication method are set forth below. Specifically, in step 201, RNIL master 13 is first set up, or registered, for subsequent patterning. Accordingly, as seen most clearly in FIG. 3, drum 19 is axially mounted onto spindle 23. Then, drum 19 is centered to less than 2 microns of the total indicated runout. Thereafter, 2 microns are diamond turned (i.e. precisely lathed) from drum 19 using diamond cutter 35 to establish zero runout (i.e. eliminate any inaccuracies in drum 19 due to being off-center or not perfectly round).

With drum 19 affixed to spindle, electroformed nickel sleeve 21 is then axially mounted onto drum 19. Preferably, sleeve 21 has a reduced thickness in the order of approximately 125 microns to 150 microns. Due to its limited thickness, a supply of air is utilized to expand sleeve 21 to permit fitted axial mounting on drum 19.

More specifically, inlets 61 on air drum 19 are adapted to receive air from a designated pneumatic device (not shown). A circumferential array of air holes 63 is provided at each end of drum 19, with each air hole 63 in fluid communication with inlets 61. As a result, the supply of air delivered to drum 19 ultimately exits through the array of air holes 63 which, in turn, causes nickel sleeve 21 to expand to the extent necessary to axially mount onto drum 19. Upon withdrawal of the air supply, sleeve 21 resiliently retracts and is thereby fittingly mounted onto drum 19 (i.e. in conformance therewith). In this capacity, air supplied to inlets 61 can be used to easily mount sleeve 21 on/off drum 19 (or other similarly sized drums utilized at other fabrication stations).

To account for any non-uniformity in its thickness, sleeve 21 is preferably diamond turned using diamond cutter 35 to ensure that the roughness of cylindrical RNIL master 13 is less than 5 nm root mean square (RMS) surface finish. As such, prior to patterning, RNIL master 13 is rendered fully concentric with an ideal surface finish, thereby minimizing the risk of any patterning inaccuracies during subsequent steps.

With RNIL master 13 mounted and prepared as such, set-up step 201 further requires laser writing instrument, or head, 37 to be properly aligned relative to RNIL master 13. As seen most clearly in FIG. 1, the longitudinal, or X, axis of laser writing head 37 is positioned so as to lie parallel with the radial direction of RNIL master 13. Disposed radially in relation RNIL master 13, light emitted from writing instrument 37 is properly focused on the surface of master 13.

With instrument 37 positioned relative to RNIL master 13, alignment fiducials are written into master 13 to ensure proper alignment during subsequent patterning steps. It should be noted that quad-focus detector 135 in instrument 37 is specifically designed to utilize astigmatic focus error signals from the feedback of light reflected from the surface of RNIL master 13 to ensure proper image focus. In other words, the two pairs of diagonally arranged quadrants of the image reflected from the surface of RNIL master 13 are focused on opposing sides of detector 135 using infinite conjugate astigmatic lenses, with one pair of diagonally arranged quadrants of the image focused behind quad-focus detector 135 and the other pair of diagonally arranged quadrants of the image focused the same distance in front of quad-focus detector 135. As a result, optical focus is achieved when the light beam size for each quadrant pair is equal.

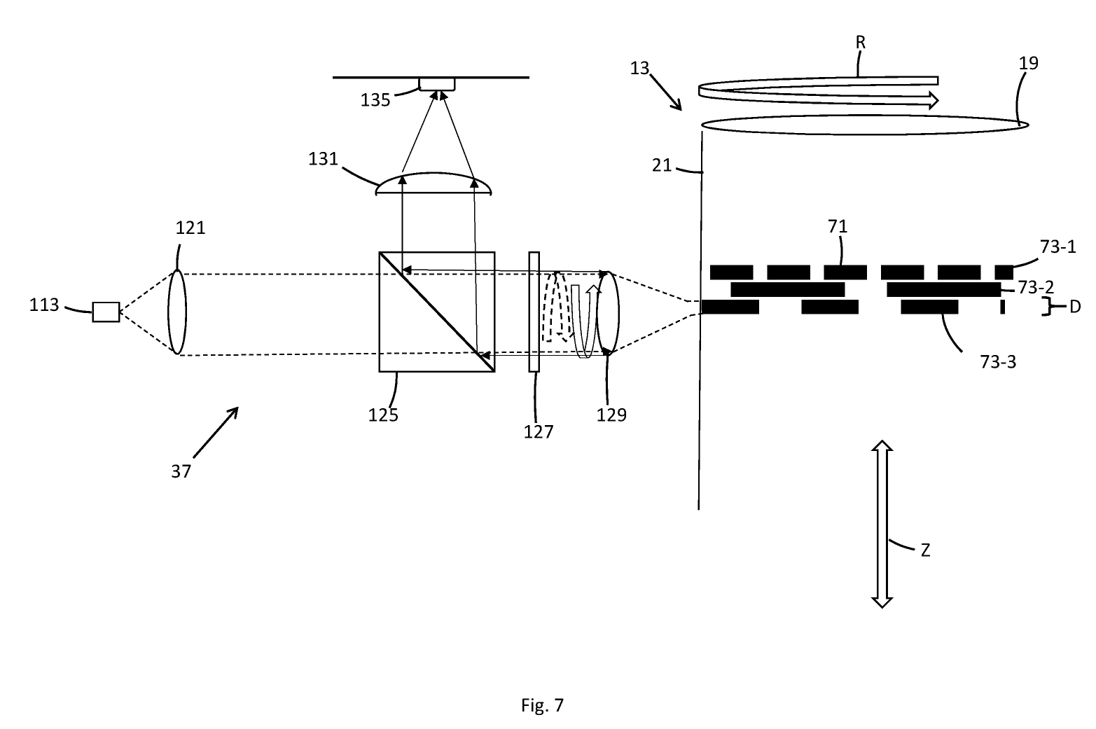

As seen most clearly in FIG. 7, alignment fiducials 71 are preferably written into RNIL master 13 by writing instrument 37 through laser ablation or other forms of laser marking. Preferably, alignment fiducials, or reference markings, 71 are written along the outer periphery of sleeve 21, outside the intended region for patterning. As shown herein, alignment fiducials 71 are preferably arranged into one or more tracks 73-1 thru 73-3, each track 73 including a linear array of pulse-type markings of modifiable length. Markings 71 are preferably formed by (i) continuously rotating drum 19, as represented by arrow R, and (ii) repeatedly pulsing UV light from laser head 37 at defined intervals for specified durations. To achieve multiple linear tracks 73, it is also understood that drum 19 is selectively axially displaced in the Z-direction (i.e. along its longitudinal axis), as represented by arrow Z. As referenced previously, the diameter, or width, D of each fiducial track 73 is defined by the wavelength of the UV light produced by laser writing instrument 37 as well as the numerical aperture of the optics for tool 37. As a feature of the invention, the data obtained from fiducials 71 enables, inter alia, sleeve 21 to be repositioned on different drums, for instance, if master fabrication steps are designed to be undertaken at separate stations.

A more detailed explanation of the fiducial marking process is set forth below. Specifically, drum 19 is preferably rotated at nominal alignment speed, such that mark detection accuracy is less than 10% of minimum mark length. For instance, with 1 MHz detector bandwidth and one million marks per revolution, then drum 19 preferably rotates at 0.1 revolution per second, or 6 rotations per minute (RPM).

Fiducial marking is accomplished by pulsing laser writing instrument 37 at high power to mark the circumference of sleeve 21 with an intermittent bit pattern of one or multiple frequencies. Adjacent tracks 73 are preferably written with one focused spot diameter of separation (i.e. approximately (0.6*laser wavelength)/(focusing lens numerical aperture)). As seen most clearly in FIG. 7, adjacent tracks 73 are written at different frequencies so that each frequency can be identified by processing the sum quad signal above detector 135 (or calculating quadrants examining quadrants (A+B)−(C+D)/sum ABCD, assuming those quadrants are in the data direction). Acute alignment is thereby achieved by utilizing a fast Fourier transform (FFT) algorithm which calculates the best axial location of rotating drum 19 (i.e. along its Z-axis) to maximize the target frequency. In this manner, Z-direction alignment at less than 10% of track width D can be achieved.

Additionally, laser writing instrument 37 pulses at high power to write one long marking (not shown) at a spindle encoder index zero location or another fixed circumferential target location. This index marking is used to find the absolute clocking alignment of sleeve 21. The length of index marking can be selected to differentiate between spurious marks or noise and the actual location of the sleeve index marking. The edges of the index marking (or, in the alternative, its center, as detected by the modulated reflection signal read in detector 135) can therefore be used for subsequent rotational alignment.

Upon completion of set-up, or alignment, step 201, nickel sleeve 21 is coated with photoresist 203 as part of step 205 shown in FIG. 6(b). Preferably, photoresist 203 represents any material that becomes photosensitized when exposed to light within a designated frequency range (e.g. MEGAPOSIT™ SPR™ 220 series photoresist manufactured by The Dow Chemical Company), with light produced by laser writing instrument 37 falling within this designated frequency range.

As seen most clearly in FIG. 1, inkjet head 39 applies a uniform coating of photoresist 203 onto the intended relief surface of sleeve 21 as drum 19 moves both rotationally as well as in the Z-direction. Inkjet head 39 is preferred for the application of photoresist 203 onto sleeve 21 due to its simplicity of construction and use, as inkjet head 39 may share certain control devices with laser writing instrument 37. However, photoresist 203 could be applied using other types of application devices, such as a flexographic head, spray coating head or micro gravure, without departing from the spirit of the present invention.

Upon completion of photoresist coating step 205, photoresist 203 is pre-baked using infrared (IR), or convection, heat 207, as part of step 209 shown in FIG. 6(c). Preferably, heat 207 is broadly applied from a designated heat source, such as an IR heater 41, as shown in FIG. 1. In this manner, heat 207 dries out some of the solvents in photoresist 203 in preparation for subsequent light exposure.

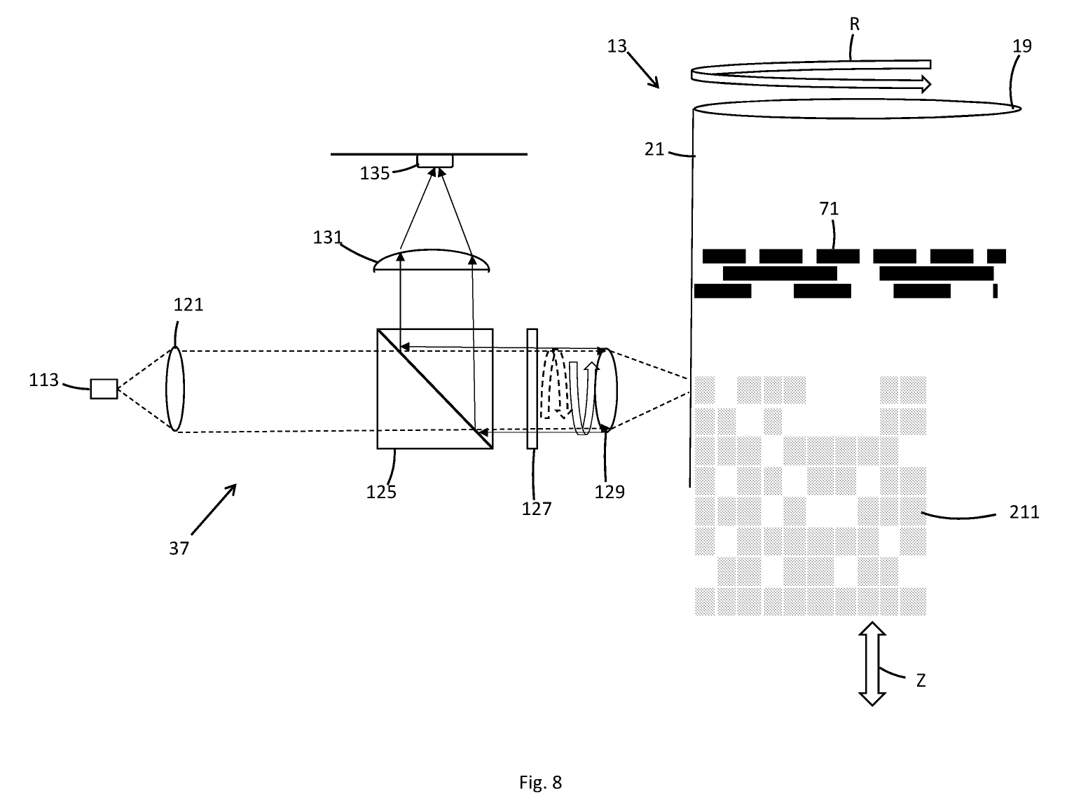

Upon completion of pre-bake step 209, laser writing instrument 37 exposes photoresist 203 in the desired feature pattern 211, as part of laser writing step 215 shown in FIG. 6(d). Specifically, laser writing head 37 produces UV light 213, the light being intermittingly pulsed from laser writing instrument 37 as drum 19 rotates and axially displaces, the pulsed emission of UV light exposing photoresist 214 in an arrangement, or matrix, of highly focused, UV light spots that together form a specific image pattern 211, as shown in FIG. 8. In other words, the photoresist 203 is exposed in a defined pattern that forms a photonegative of a mask, or stencil, to be used in a subsequent master fabrication step, as will be explained further below.

In order to laser write in the desired feature pattern 211, images to be written onto sleeve 21 are preprocessed, with target encoder positions calculated relative to known location information for fiducials 71. For patterning at different heights, each layer would have its own image to be written at a specific stage. The collection of images represents each patterning layer for RNIL master 13 in sequence from the bottom layer to the top layer.

The collection of images to be written into photoresist 203 on sleeve 21 are then loaded into a buffer for the controller of laser writing instrument 37. Using the images, laser writing instrument 37 pulses, with overlap and at a power level corresponding to rotation speed of drum 19, to provide the targeted photoresist exposure energy.

It should be noted that the laser writing process can be triggered by (i) comparison to spindle 23 and/or the Z axis encoder position of drum 19 while in targeted focus for pixels or bits to be written, or (ii) sequentially through incremental counting of encoder ticks correlating to a particular bit pattern. For instance, rotational and axial displacement of drum 19 could be regulated so that printing occurs basically along a single, acute, helical path (i.e. thread). Very high writing speeds are obtainable using this technique, thereby significantly reducing the time requirement associated with the overall fabrication process, which is a principal object of the present invention.

As referenced above, the design of laser writing instrument 37 allows for the emission of highly focused UV light spots, each spot having a width of approximately 400 nm. By intermittingly pulsing UV light spots of a limited width, light patterns can be emitted onto sleeve 21 with considerable precision and high resolution. Referring now to FIG. 9(b), a hemispheric-shaped immersion lens 161 can be incorporated into the optical system 115 for instrument 37 in order to increase the numerical aperture of optical system 115 and thereby reduce the width of light pulses generated by instrument 37. For example, a diamond-based immersion lens could be used to reduce the width of light pulses generated from laser writing instrument 37 to less than 50 nm. As can be seen, hemispherical immersion lens 161 is oriented with rounded, hemispherical surface 161-1 directly opposing, or facing, objective lens 129. Opposite face 161-2 of immersion lens 161 directly faces the rounded outer contour of RNIL master 13. In lieu of a generally flat construction, face 161-2 of immersion lens 161 is preferably slightly concaved to match the slight outward contour of RNIL master 13, thereby providing immersion lens 161 with a relatively high refractive index (e.g. 1.5 for glass, 2.4 for diamond), which is preferably equal to or greater than the refractive index of photoresist 203.

By comparison, a diamond-based immersion lens (not shown) would preferably lie in near tangential contact with RNIL master 13. More specifically, the immersion lens would preferably be spaced away from photoresist 203 on RNIL master 13 a distance which is less than approximately one-quarter the wavelength of the UV light emitted from laser writing instrument 37 (e.g. approximately 100 nm for 405 nm UV light) so as to achieve evanescent coupling. As an added benefit, the near tangential positioning of a diamond-based immersion lens relative to RNIL master 13, as well as the hardness and strength of the diamond material, would allow for the immersion lens to shear, or shave, any irregularities or impurities from the surface of photoresist 203 (e.g. dust or other similar particulates that would otherwise interfere with certain steps in the RNIL master fabrication process).

Upon completion of laser writing step 215, the RNIL master manufacturing process pauses for approximately 30-120 minutes in a rest environment at greater than 50% humidity in order to rehydrate resist 203 to complete reaction. Thereafter, photoresist 203 is post-baked as part of step 219 shown in FIG. 6(e). Preferably, light-exposed resist 203 is post-baked using relatively disperse IR heat 217 generated from IR heater 41. The application of infrared (or, alternatively, convection) heat to RNIL master 13 serves to, among other things, smooth out the feature image 211 written into photoresist 203.

Upon completion of post-baking step 219, a chemical developer solution is applied to RNIL master as part of step 223 shown in FIG. 6(f). Preferably, the developer is any suitable chemical developer solution for removing, or dissolving, positive-tone photoresist 203 that has been exposed to IR light. For instance, the chemical developer solution may be in the form of MF-24A™ or MF-26A™ developer, both of which are manufactured by The Dow Chemical Company. Although not shown herein, the chemical developer solution utilized in step 223 could be alternatively selected to dissolve or remove any unexposed areas of negative-tone resist 203 applied to nickel sleeve 21. As a result of chemical development step 223, the remaining photoresist 203 effectively creates a mask, or stencil, 221 on nickel sleeve 21 (i.e. a surface pattern is created on the exterior of sleeve 21 using the remaining photoresist 214).

Thereafter, as part of step 225 shown in FIG. 6(g), nickel sleeve 21 is electroplated through developed mask 221 by immersing nickel sleeve 21 in an electroplating chemical solution (e.g. contained within a designated pan 43) and, in turn, applying current thereto (e.g. through slip ring 71 in conductive communication with sleeve 21, as shown in FIG. 2). An example of a chemical solution to be used in the aforementioned electroplating process is the Elevate® Ni 5930 nickel plating solution, which is manufactured by Technic, Inc. It is to be understood that electroplating in step 225 can occur either with sleeve 21 mounted on drum 19, as shown herein, or by removing sleeve 21 and electroplating at a separate station.

Upon completion of electroplating step 225, RNIL master 13 is diamond turned in step 227, as shown in FIG. 6(h). Specifically, using diamond cutter 35, the electroplated nickel sleeve 21 is diamond turned to the targeted feature height, which is preferably offset from (i.e. above) the surface of the remaining photoresist 214.

In final step 229, as shown in FIG. 6(i), any remaining photoresist 203 on RNIL master 13 is stripped, or dissolved, using an appropriate chemical solution, such as Microposit™ Remover 1165 solution, which is manufactured by The Dow Chemical Company. The aforementioned process is repeated, as needed, for each successively higher geometry that is desired. In other words, the process is repeated for each level in the desired nanoscale structure. For all subsequent levels, it is to be understood that the written fiducials from the first level are reused for alignment only and, as such, no new fiducial markings or tracks need be written in metal sleeve 21. Overall, the entire RNIL master manufacturing process set forth in detail above can be integrated on a singular mastering platform or can be done in separate operations with wet chemical processes done offline.

It should be noted that the focus error signal may be used in situ at low power for (i) measuring heights and profiling the existing structure on sleeve 21 as an intermediate step or (ii) mapping the surface where the FES signal strength normalized by the sum of the detectors is directly proportional to height above the surface. Thus, calibration is achieved by moving the X axis relative to the cylinder surface.

### System Variations and Alternative Embodiments

The invention described in detail above is intended to be merely exemplary and those skilled in the art shall be able to make numerous variations and modifications to it without departing from the spirit of the present invention. All such variations and modifications are intended to be within the scope of the present invention as defined in the appended claims.

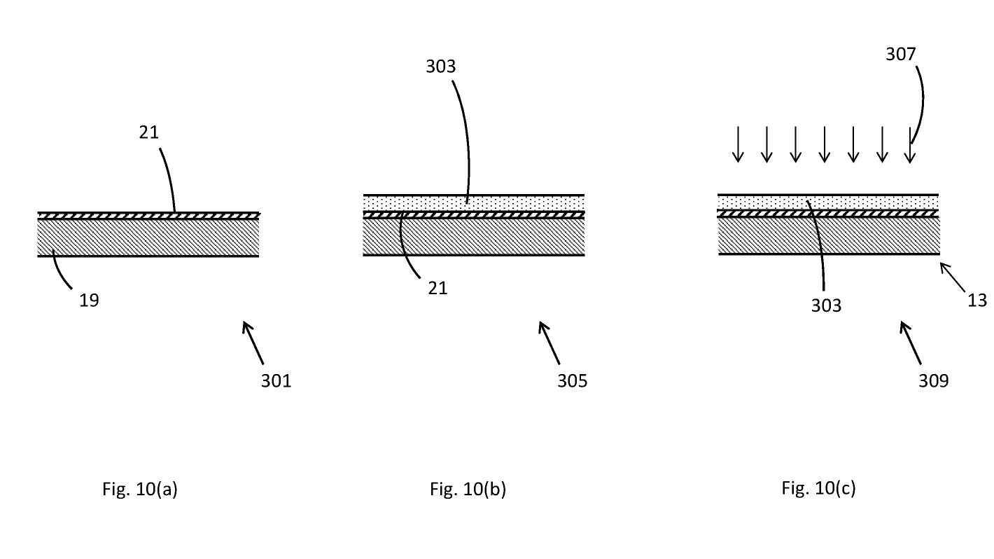

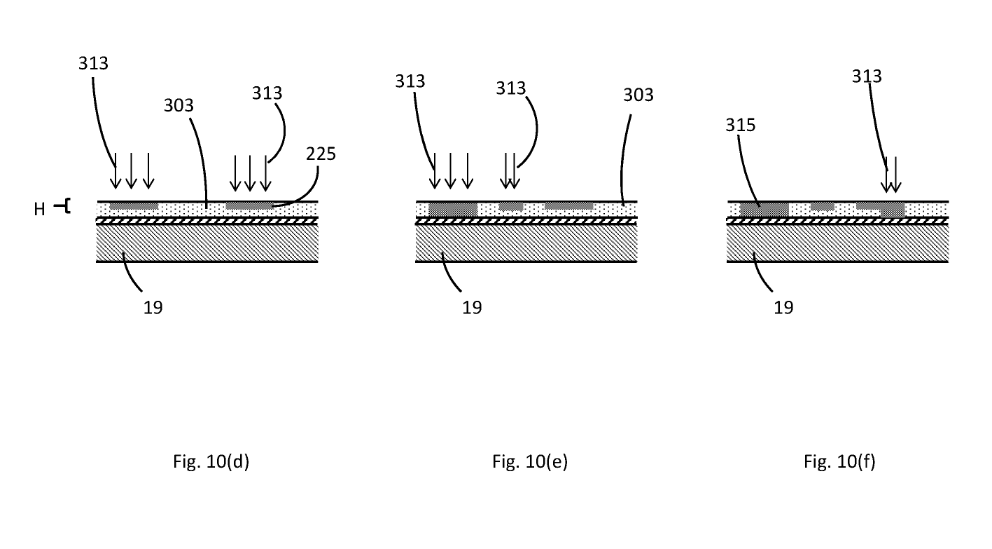

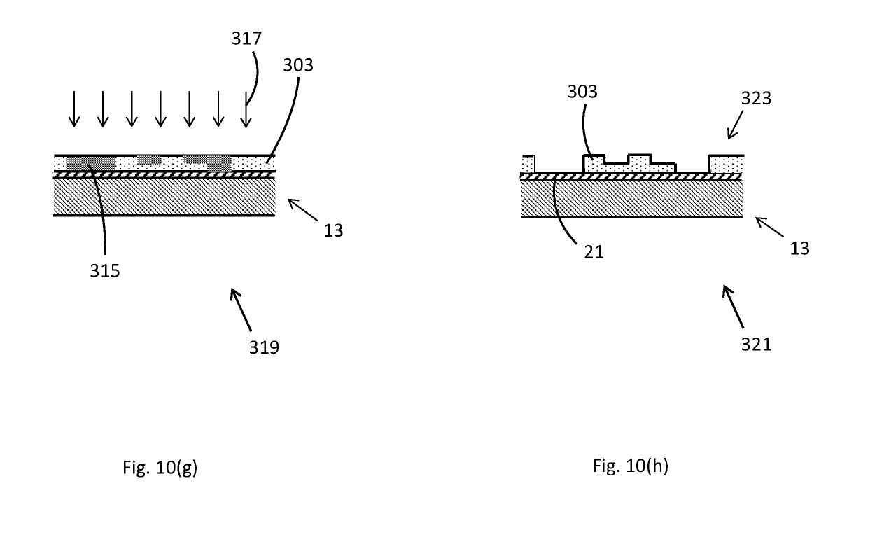

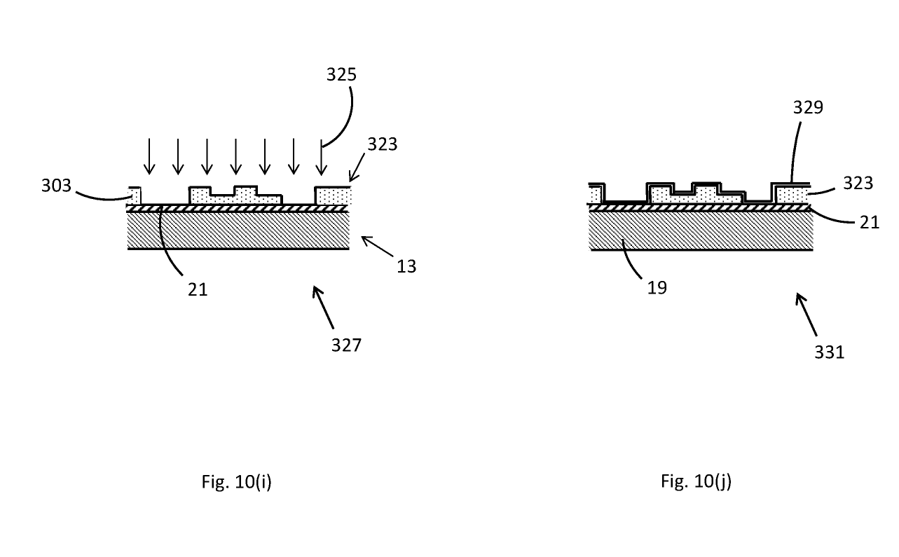

For example, the master construction method could be modified, as needed, to allow for the manufacture of a NIL master 13 with highly precise, multi-dimensional, nanoscale features through a relatively simple and efficient alternative patterning process. Specifically, as set forth in detail in FIGS. 10(i)-(j), a modified RNIL master fabrication method is disclosed.

The modified RNIL master manufacturing process is similar to the method set forth in FIGS. 6(a)-(i) in that, as the primary step in the modified process, RNIL master 13 is set-up for subsequent patterning, the aforementioned set-up step being identified generally by reference numeral 301 in FIG. 10(a). Thereafter, RNIL master 13 is coated with photoresist 303 (e.g. MEGAPOSIT™ SPR™ 220 series photoresist manufactured by The Dow Chemical Company), this photoresist coating step being identified generally by reference numeral 305 in FIG. 10(b). Finally, the photoresist 303 is pre-baked with infrared heat 307 (preferably at 105° C. for 90 seconds) to remove solvent therefrom, this pre-baking step being identified generally by reference numeral 309 in FIG. 10(c),

The modified RNIL master manufacturing process differs from the method set forth in FIGS. 6(a)-(i) primarily in the manner in which the feature pattern is formed in sleeve 21 of RNIL master 13. Generally, the desired image pattern is written into photoresist 303 on RNIL master 13 using UV light pulsed as a matrix of highly focused spots, wherein the pulse of UV light for each spot is scaled in terms of intensity, duration and/or number to vary the depth of UV light exposure, this multi-stepped, laser image writing, or patterning, process being illustrated in FIGS. 10(d)-(f).

More specifically, using laser writing tool 37, photoresist 303 is illuminated with UV light 313. As can be appreciated, photoresist 303 becomes soluble when exposed to UV light 313 (i.e. chemical bonds are broken in photoresist 303 which allows for subsequent dissolution/removal). As shown in FIGS. 10(d)-(f), UV light 313 is generated as a matrix, or array, of highly focused spots, or pixels, which are arranged in accordance with an image file representing a photonegative 315 of the desired feature pattern.

As an inherent chemical property which is discovered and, in turn, exploited as part of the present invention, UV light 313 develops photoresist 303 at a depth H that is dependent upon the intensity and duration of the illumination of UV light 313 as well as the chemical attributes and thickness of photoresist 303. This effect is created because photoresist 303 is naturally opaque (due to the presence of a photodye) and only becomes transparent upon development. As such, UV light 313 is not initially able to penetrate through the entirety of photoresist 303. Rather, the interior portion of photoresist 303 cannot receive UV light 303 until the outermost regions first become developed. Accordingly, as part of the writing process shown in FIGS. 10(d)-(f), a precise, multi-dimensional, configuration of photonegative 315 can be developed in photoresist 303 by acutely directing UV light 313 onto photoresist 303 (a) in a specific pattern, (b) for a specific duration and (c) at a specific intensity.

In other words, precise UV light application can create different depths, or steps, of photoresist exposure. For instance, a multi-stepped photosensitizing process is shown in FIGS. 10(d)-(f) for ease of understanding. Specifically, 0-10 pulses of UV light 313 of fixed duration are applied for each pixel, or spot, on photoresist 303, thereby creating a step-like, three-dimensional exposure pattern, or photonegative, 315 in photoresist 303. As a key feature of the invention, the multi-dimensional, or stepped, exposure pattern 315 can be achieved through a single light application process (i.e. a sequential, iterative or multi-staged patterning process for each feature pattern layer in RNIL master 13 is not required).

For purposes of illustration only, it is envisioned that photoresist 303 has a thickness preferably in 2-10 microns range (e.g. 4.5 microns). Additionally, with respect to the Intensity and duration of UV light 313, it is envisioned that the energy of UV light 313 (i.e. the product of the UV light power and duration) be scaled dependent upon, inter alia, spot size, photoresist thickness, photoresist sensitivity/type as well as desired penetration depth (e.g. 10%, 25%, 50% of energy required to fully penetrate photoresist). For instance, the energy of UV light 313 is probably in the order of about 20-1000 mjoules/cm².

Upon completion of the laser writing process, photoresist 303 is post-baked on RNIL master 13 using IR heat 317, the post-baking step being identified generally by reference numeral 319 in FIG. 10(g). As can be appreciated, post-baking step 319 prepares the photosensitized resist, or photonegative, 315 for subsequent development.

Thereafter, chemical developer (e.g. Microposit™ Remover 1165 solution, which is manufactured by The Dow Chemical Company) is applied to the entire exposed outer surface of RNIL master 13, this developing step being identified generally by reference numeral 321 in FIG. 10(h). As a result, the UV-exposed, positive-type, resist 315 is removed, or dissolved, from master 13, with the desired feature pattern mask, or stencil, 323 remaining on sleeve 21. It should be noted that the application of chemical developer also incidentally dissolves a relatively small percentage ( 1/100) of the remaining, non-photosensitized, resist 303, this removal being compensated for in a subsequent step.

After completion of developer application step 321, non-sensitized photoresist 303 is further post-baked with IR heat 325 to achieve the necessary hardness, this additional post-baking step being identified generally by reference number 327 in FIG. 10(i). Thereafter, in the final step of the manufacturing process, a nickel coating 329 is applied onto the entire exposed surface of NIL master 13 through electroless nickel plating or electroplating, this coating application step being identified generally by reference numeral 331 in FIG. 10(j). As can be appreciated, the thickness of coating 329 is preferably calculated based on the degree of dissolution of hardened resist 323 during prior developer step 321 (i.e. to ultimately achieve the desired pattern height).

What is claimed is:

1. A method of manufacturing a roller-type nanoimprint lithography (RNIL) master, the method comprising the steps of:
(a) mounting an RNIL master on a rotatable axle, the rotatable axle having a longitudinal axis;
(b) applying a layer of photoresist on the RNIL master;
(c) positioning a writing instrument in relation to the RNIL master, the writing instrument being adapted to emit pulses of light of a first wavelength; and
(d) exposing the photoresist in a defined pattern on the RNIL master using pulses of light emitted from the writing instrument.

2. The method as claimed in claim 1 wherein the RNIL master is adapted to rotate about the longitudinal axis of the rotatable axle.

3. The method as claimed in claim 2 wherein the RNIL master is adapted to move linearly in parallel with the longitudinal axis of the rotatable axle.

4. The method as claimed in claim 3 wherein the RNIL master is adapted for movement in synchronization with pulses of light emitted from the writing instrument to expose the layer of photoresist in the defined pattern.

5. The method as claimed in claim 4 wherein the RNIL master comprises a cylindrical metal sleeve which is removably mounted onto a drum, the drum being fixedly mounted onto the rotatable axle.

6. The method as claimed in claim 3 wherein the layer of photoresist is applied onto the RNIL master as the RNIL master rotates about the longitudinal axis of the rotatable axle.

7. The method as claimed in claim 6 wherein the layer of photoresist is applied onto the RNIL master using an inkjet head.

8. The method as claimed in claim 3 wherein the writing instrument is fixedly mounted in relation to the RNIL master.

9. The method as claimed in claim 8 wherein pulses of light emitted from the writing instrument are registered on the RNIL master in the defined pattern using at least one alignment fiducial on the RNIL master.

10. The method as claimed in claim 9 wherein pulses of light emitted from the writing instrument are registered on the RNIL master in the defined pattern using multiple linear tracks of alignment fiducials of varying frequency.

11. The method as claimed in claim 4 wherein the step of exposing the layer of photoresist in the defined pattern comprises the steps of:
(a) exposing the layer photoresist at various depths to create a light-sensitized pattern in the layer photoresist; and
(b) developing the layer of photoresist.

12. The method as claimed in claim 11 wherein exposing the layer of photoresist at various depths is accomplished by modifying the pulses of light emitted from the writing instrument in terms of at least one of duration, intensity, and number.

13. The method as claimed in claim 11 wherein developing the layer of photoresist removes the light-sensitized pattern in the layer of photoresist from the RNIL master.

14. The method as claimed in claim 13 further comprising the step of applying an outer metal coating onto the RNIL master.

15. The method as claimed in claim 5 wherein the step of exposing the layer of photoresist in the defined pattern comprises the steps of:
(a) exposing the layer of photoresist in a light-sensitized pattern;
(b) developing the layer of photoresist; and
(c) electroplating the metal sleeve.

16. The method as claimed in claim 15 wherein developing the photoresist removes the light-sensitized pattern in the layer of photoresist from the RNIL master.

17. The method as claimed in claim 15 wherein the metal sleeve is electroplated through any of the layer of photoresist remaining on the RNIL master.

18. The method as claimed in claim 17 further comprising the step of diamond turning the metal sleeve to a desired height.

19. The method as claimed in claim 18 further comprising the step of stripping any of the layer of photoresist remaining on the RNIL master.
